(19) United States
(12) Patent Application Publication
(10) Pub. No.: US 2023/0145436 A1
(43) Pub. Date: May 11, 2023

(54) METHOD AND APPARATUS FOR ENERGY SELECTIVE DIRECT ELECTRON IMAGING

(71) Applicant: DIRECT ELECTRON, LP, San Diego, CA (US)

(72) Inventors: Benjamin BAMMES, San Diego, CA (US); Robert BILHORN, San Diego, CA (US)

(73) Assignee: DIRECT ELECTRON, LP, San Diego, CA (US)

(21) Appl. No.: 17/905,128

(22) PCT Filed: Mar. 1, 2021
(86) PCT No.: PCT/US2021/020306

§ 371 Date: Aug. 26, 2022

Related U.S. Application Data
(60) Provisional application No. 62/983,346, filed on Feb. 28, 2020.

(51) Int. Cl. H01J 37/295

(52) U.S. Cl. CPC H01J 37/2955; H01J 2237/2803; H01J 2237/2446; H01J 2237/24475; H01J 2237/24495

(57) ABSTRACT

A method of, and a detector for, performing energy sensitive imaging of ionizing radiation are provided, including acquiring a first frame having a plurality of pixels, each pixel of the plurality having an energy of detection and a location; grouping, into a cluster, pixels of the plurality having an energy of detection above a predetermined threshold and a location along with at least one other pixel also having an energy of detection above the predetermined threshold and being within a predetermined distance of the location; summing the energy of detection of all pixels within the grouped cluster to determine a cluster energy; determining a location of the cluster based on a distribution and an intensity of the summed energy of detection; and generating an image of the cluster based on the determined cluster energy and the determined location of the cluster.

### CROSS-REFERENCE TO RELATED APPLICATIONS

This application claims benefit to U.S. Provisional Application No. 62/983,346, filed Feb. 28, 2020, which is incorporated herein by reference in its entirety.

### STATEMENT OF FUNDING ACKNOWLEDGEMENT

The inventors acknowledge the support provided by the U.S. Department of Energy, Office of Science, under Award Number DE-SC0019681.

### FIELD

The present disclosure relates to a system, apparatus, and method for performing energy sensitive imaging of ionizing radiation in an electron microscope with the ability to determine both the position and energy of individual energetic particles incident on a detector. In particular, the present disclosure relates to a system, apparatus, and method for imaging electrons in an electron microscope with the ability to determine both the position and energy of individual electrons incident on a detector.

### BACKGROUND

Electron backscatter diffraction (EBSD) is a powerful and widely used technique in scanning electron microscopy for characterizing crystalline or polycrystalline materials. EBSD facilitates measurement of crystallographic orientation, texture, defects, strain, grain size and boundary types, and phase identification with spatial resolution of tens of nanometers. See, e.g., Schwarzer R. A., Field D. P., Adams B. L., Kumar M., & Schwartz A. J., “Present state of electron backscatter diffraction and prospective developments,” Electron backscatter diffraction in materials science (2009), Springer: 1-20. Characterizing this microstructure is advantageous for understanding the properties and performance of materials, including engineered materials, microelectronics, materials for renewable energy, and geological materials.

While tremendous gains in the analysis and indexing of EBSD patterns have occurred, additional promise in advancing new capabilities for EBSD lies in profiting from the collection of EBSD patterns using high performance detectors. Advanced applications of EBSD, such as three-dimensional (3D) serial sectioning and in situ testing (e.g., mechanical loading, thermal excursions), demand high speed pattern acquisition while preserving the pattern quality for indexing. In parallel, the ability to discriminate the energy distribution of the exit electrons from the specimen and the energy distribution on the detector is desirable for understanding the physics of electron diffraction, improving pattern quality to extract meaningful features, and even the potential application of EBSD as a spectroscopy tool.

Some EBSD detectors use a scintillator to convert incoming electrons to light, which is then transmitted through lenses to a CCD-based or CMOS-based image sensor. Indirect detection through a scintillator and lenses attenuates the sensitivity of these detectors. See, e.g., Wilkinson A. J., Moldovan G., Britton T. B., Bewick A., Clough R. N., & Kirkland A. I., “Direct Detection of Electron Backscatter Diffraction Patterns,” Physical Review Letters (2013), 111: 065506. The lenses of these detectors may also introduce distortions, which limit the accuracy and resolution of the technique. See, e.g., Britton T. B., Maurice C., Fortunier R., Driver J. H., Day A. P., Meaden G., Dingley D. J., Mingard K., & Wilkinson A. J., “Factors affecting the accuracy of high resolution electron backscatter diffraction when using simulated patterns,” Ultramicroscopy (2010), 110: 1443-1453.

Further compounding the limited sensitivity of current EBSD detectors is the fact that they cannot be tuned to detect only electrons within a certain energy range. (Kikuchi bands in EBSD patterns are generated by electrons that lose no more than ˜20% of their energy in the specimen.) Some EBSD methods, in which all electrons are collected regardless of energy, have significantly lower contrast than if energy filtering is applied so that only low-loss electrons are collected. See, e.g., Deal A., Hooghan T., & Eades A., “Energy-filtered electron backscatter diffraction,” Ultranicroscopy (2008), 108: 116-125.

Monolithic active pixel sensors (MAPS) are used for imaging electrons in transmission electron microscopes (TEM). These direct detectors have been beneficial for imaging radiation-sensitive materials, such as biological materials, because they have unprecedented sensitivity and spatial resolution capabilities. These detectors can function at, for example, 300 keV and even 200 keV. At lower electron energies, however, their performance degrades. Therefore, these detectors have had limited usefulness for low-energy electron microscopy techniques, such as EBSD.

Digital complementary metal-oxide semiconductor (CMOS) hybrid pixel detectors (HPDs) have been used with some success for collecting low-energy electron microscopy images, including EBSD. The architecture of these HPD detectors allows for so-called “energy-filtered EBSD” by setting one or more threshold values, such that only electrons with energy greater than the threshold value(s) are recorded. See, e.g., Vespucci S., Winkelmann A., Naresh-Kumar G., Mingard K. P., Maneuski D., Edwards P. R., Day A. P., O'Shea V. O., & Trager-Cowan C., “Digital direct electron imaging of energy-filtered electron backscatter diffraction patterns,” Physical Review B (2015), 92: 205301. However, except for detecting whether electron energy is above or below a threshold value, these detectors cannot measure the energy of each incident electron.

The present disclosure addresses the above-described deficiencies of current detectors and methodologies.

The foregoing “Background” description is for the purpose of generally presenting the context of the disclosure. Work of the inventors, to the extent it is described in this background section, as well as aspects of the description which may not otherwise qualify as prior art at the time of filing, are neither expressly or impliedly admitted as prior art against the present invention.

### SUMMARY

The present disclosure relates to a system, apparatus, and method for energy selective direct electron imaging.

The present disclosure additionally relates to a method of performing energy sensitive imaging of ionizing radiation, including: acquiring a first frame, the first frame including a plurality of pixels, each pixel of the plurality of pixels having an energy of detection and a location; grouping, into at least one cluster, pixels of the plurality of pixels having an energy of detection above a predetermined threshold and a location along with at least one other pixel also having an energy of detection above the predetermined threshold and being within a predetermined distance of the location; summing the energy of detection of all pixels within the grouped at least one cluster to determine a cluster energy; determining a location of the at least one cluster based on a distribution and an intensity of the summed energy of detection of the pixels in the at least one cluster; and generating an image of the at least one cluster based on the determined cluster energy and the determined location of the at least one cluster.

The present disclosure additionally relates to a detector apparatus, including: an array of a plurality of detector elements, each element of the plurality of detector elements including a monolithic active pixel sensor (MAPS) having an epitaxial silicon layer configured to be exposed to backscattered electrons and to prevent charge from being trapped at a surface thereof; and processing circuitry configured to acquire a first frame, the first frame including a plurality of pixels, each pixel of the plurality of pixels having an energy of detection and a location; group, into at least one cluster, pixels of the plurality of pixels having an energy of detection above a predetermined threshold and a location along with at least one other pixel also having an energy of detection above the predetermined threshold and being within a predetermined distance of the location; sum the energy of detection of all pixels within the grouped at least one cluster to determine a cluster energy; determine a location of the at least one cluster based on a distribution and an intensity of the summed energy of detection of the pixels in the at least one cluster; and generate an image of the at least one cluster based on the determined cluster energy and the determined location of the at least one cluster.

The present disclosure additionally relates to a detector apparatus, including: an array of a plurality of detector elements, each detector element of the plurality of detector elements being configured to detect ionizing radiation and to convert the detected ionizing radiation into a photo charge value corresponding to an intensity of the detected ionizing radiation; and processing circuitry configured to acquire a first frame, the first frame including a plurality of pixels, each pixel of the plurality of pixels having an energy of detection and a location; group, into at least one cluster, pixels of the plurality of pixels having an energy of detection above a predetermined threshold and a location along with at least one other pixel also having an energy of detection above the predetermined threshold and being within a predetermined distance of the location; sum the energy of detection of all pixels within the grouped at least one cluster to determine a cluster energy; determine a location of the at least one cluster based on a distribution and an intensity of the summed energy of detection of the pixels in the at least one cluster; and generate an image of the at least one cluster based on the determined cluster energy and the determined location of the at least one cluster.

In one embodiment, the method further includes: generating a first combined data set including the acquired first frame, the first frame including a catalog of the cluster energy of the at least one cluster and the location of the at least one cluster.

In one embodiment, the image of the at least one cluster is generated based on a number of the at least one cluster having the cluster energy exceeding a predetermined cluster energy for each determined location of the at least one cluster.

In one embodiment, the image of the at least one cluster is generated based on a number of the at least one cluster having the cluster energy below a predetermined cluster energy for each determined location of the at least one cluster.

In one embodiment, the image of the at least one cluster is generated based on a number of the at least one cluster having the cluster energy within a predetermined cluster energy range for each determined location of the at least one cluster.

In one embodiment, the image of the at least one cluster is generated based on a corresponding energy of detection of said each pixel of the plurality of pixels grouped into the at least one cluster.

In one embodiment, the method further includes: determining a correlation between a structure or a property of a specimen and the first combined data set.

In one embodiment, the method further includes: scanning a beam of electrons over the specimen in a pattern, the beam of electrons having a plurality of dwell positions located over the specimen; acquiring an energy-selective image of the electrons for each position of the plurality of dwell positions; and generating a second combined data set including the acquired energy-selective image of the electrons for said each position of the plurality of dwell positions.

In one embodiment, the method further includes: generating a combined electron backscatter diffraction (EBSD) map including the second combined data set having the energy-selective image of the electrons for said each position of the plurality of dwell positions.

In one embodiment, the method further includes: for a second acquired frame having a second plurality of pixels, each pixel of the second plurality of pixels having an energy of detection and a location, repeating the steps of grouping, into another at least one cluster, said each pixel of the second plurality of pixels into at least one second cluster, summing the energy of detection of all pixels within the grouped at least one second cluster to determine a second cluster energy, determining a location of the at least one second cluster, and generating an image of the at least one cluster and the at least one second cluster.

The foregoing paragraphs have been provided by way of general introduction, and are not intended to limit the scope of the following claims. The described embodiments, together with further advantages, will be best understood by reference to the following detailed description taken in conjunction with the accompanying drawings.

### BRIEF DESCRIPTION OF THE DRAWINGS

A more complete appreciation of the disclosure and many of the attendant advantages thereof will be readily obtained as the same becomes better understood by reference to the following detailed description when considered in connection with the accompanying drawings, wherein:

FIG. 1A shows the detected fraction of incident individual electrons as a function of electron energies (simulated and experimental), according to an embodiment;

FIG. 1B shows a cropped region of a single frame showing a sparse distribution of single electrons detected by a direct electron detector, according to an embodiment;

FIG. 1C shows a schematic of a single electron detection event at a single pixel, according to an embodiment;

FIG. 1D shows a schematic of a single electron detection event over multiple pixels, according to an embodiment;

FIG. 2A shows a series of histograms of the detected fraction of incident individual electrons as a function of event intensity for events detected by a direct electron detector at different incident electron energies, according to an embodiment;

FIG. 2B shows the measured linearity of response to electron energy of single electrons detected by a direct electron detector, according to an embodiment;

FIG. 3A shows electron backscatter diffraction (EBSD) patterns of single-crystal Si acquired using a phosphor+CCD camera, according to an embodiment;

FIG. 3B shows EBSD patterns of single-crystal Si acquired using a direct electron detector, according to an embodiment;

FIG. 3C shows simulated EBSD patterns of single-crystal Si, according to an embodiment;

FIG. 4A shows a schematic of the integration of fast detector frame readouts acquired for multiple frames, each of which shows a sparse distribution of single electrons detected by a direct electron detector, according to an embodiment;

FIG. 4B shows a multi-dimensional data set of integrated and energy-filtered EBSD patterns based on the frames of FIG. 4A, according to an embodiment;

FIG. 4C shows a distribution of pixel intensities in the integrated and energy-filtered EBSD patterns of FIG. 4B, according to an embodiment;

FIG. 4D shows the EBSD map of FIG. 4B, modified to include the electron energy distribution of FIG. 4C by applying a grayscale gradient corresponding to electron energies over the EBSD map shown in FIG. 4B, according to an embodiment;

FIG. 5A shows the detective quantum efficiency (DQE) at 300 keV for a frontside-illuminated monolithic active pixel sensor (MAPS) detector operated in integrating mode, according to an embodiment;

FIG. 5B shows the DQE at 300 keV for a frontside-illuminated MAPS detector operated in electron counting mode, according to an embodiment;

FIG. 5C shows the modulation transfer function (MTF) and DQE at 80 keV for a frontside-illuminated MAPS detector operated in integrating mode, according to an embodiment;

FIG. 5D shows the MTF and DQE at 80 keV for a backside-illuminated MAPS direct electron detector operated in integrating mode, according to an embodiment;

FIG. 5E shows the MTF at 20 keV and 40 keV for a backside-illuminated MAPS direct electron detector operated in integrating mode, according to an embodiment;

FIG. 5F shows a schematic cross-section of a MAPS direct electron detector, according to an embodiment;

FIG. 5G shows a schematic cross-section of a portion of the MAPS direct electron detector of FIG. 5F, according to an embodiment;

FIG. 5H shows a schematic cross-section of a portion of the MAPS direct electron detector of FIG. 5F, having a handling wafer bonded to a circuitry side of the detector, according to an embodiment;

FIG. 5I shows a schematic cross-section of a portion of a MAPS direct electron detector having a handling wafer bonded to a circuitry side of the detector and from which a substrate portion of an original wafer has been removed, according to an embodiment:

FIG. 5J shows a graph of average event size as a function of accelerating voltage, according to an embodiment;

FIG. 5K shows a graph of mean event intensity as a function of accelerating voltage, according to an embodiment;

FIG. 6 is a schematic diagram of a computer for controlling components of the system including a direct electron detector, according to an embodiment: and

FIG. 7 is a flow chart illustrating steps of a method for performing energy sensitive imaging of ionizing radiation, according to an embodiment.

### DETAILED DESCRIPTION

The terms “a” or “an”, as used herein, are defined as one or more than one. The term “plurality”, as used herein, is defined as two or more than two. The term “another”, as used herein, is defined as at least a second or more. The terms “including” and/or “having”, as used herein, are defined as comprising (i.e., open language). Reference throughout this disclosure to “one embodiment”, “certain embodiments”, “an embodiment”, “an implementation”, “an example”, or similar terms means that a particular feature, structure, or characteristic described in connection with the embodiment is included in at least one embodiment of the present disclosure. Thus, the appearances of such phrases or in various places throughout this disclosure are not necessarily all referring to the same embodiment. Furthermore, the particular features, structures, or characteristics may be combined in any suitable manner in one or more embodiments without limitation.

Information about a specimen can be encoded in the trajectory and energy of interacting electrons. Electron images often suffer from poor signal-to-noise ratio (SNR). The degradation of SNR is caused by electrons that that do not carry image information. These electrons are often of different energy than useful signal electrons, so if they can be filtered out and removed, the resulting image SNR can be improved. In one example, an image can be generated based on a number of a detection event or a grouping of detection events having an energy exceeding a predetermined energy threshold for each location of the registered detection events. In another example, an image can be generated based on a number of the detection event or the grouping of detection events having said energy falling below a predetermined energy threshold for said each location of the registered detection events. In another example, an image can be generated based on a number of the detection event or the grouping of detection events having said energy falling within a predetermined energy range for said each location of the registered detection events. In another example, an image can be generated based on the detection event or the grouping of detection events having said energy corresponding to a predetermined energy for said each location of the registered detection events.

The emergence of modern direct electron detectors (DEDs) has led to breakthroughs in transmission electron microscopy, as well as in EBSD. See, e.g., Wilkinson et al. (above), see also Vespucci S. et al (above). The ultra-high sensitivity of these detectors provides much improved pattern quality, and allows the detection of higher order electron diffraction features. This sensitivity also promises low voltage and/or low current EBSD.

Low voltages can lead to smaller interaction volume in the material and therefore better spatial resolution. Low currents are amenable to orientation mapping in dose-sensitive or non-conductive materials (e.g., geological samples, ceramics). Described herein is a new large-format direct electron detector (DED), also referred to as a DED sensor, with single-electron sensitivity to energies commonly used for EBSD, from, for example, 3 kV to 30 kV. As described herein, the DED sensor for charged particles can be read out such that some pixels are set to have zero integration time. These zero-integration-time pixels can be grouped according to the row index, column index, position in the readout kernel, output channel on the detector, or other characteristic of the detector architecture. A value (such as the mean or median) can be calculated for each group of zero-integration-time pixels, and this value can be subtracted from all nonzero-integration-time pixels that would be similarly grouped on the detector. The DED sensor can include, for example, 2048×2048 pixels and operate with either rolling-shutter or global-shutter continuous high-speed readout.

Some methods can capture position information but are unable to record energy information. A DED sensor, as described herein, can record position information and the energy of the interacting charged particle. Monte Carlo simulations of the DED sensor, as described herein, show that the detection efficiency can exceed 80% for all scanning electron microscope (SEM) energies above 5 kV and approach 100% at 8 kV and above.

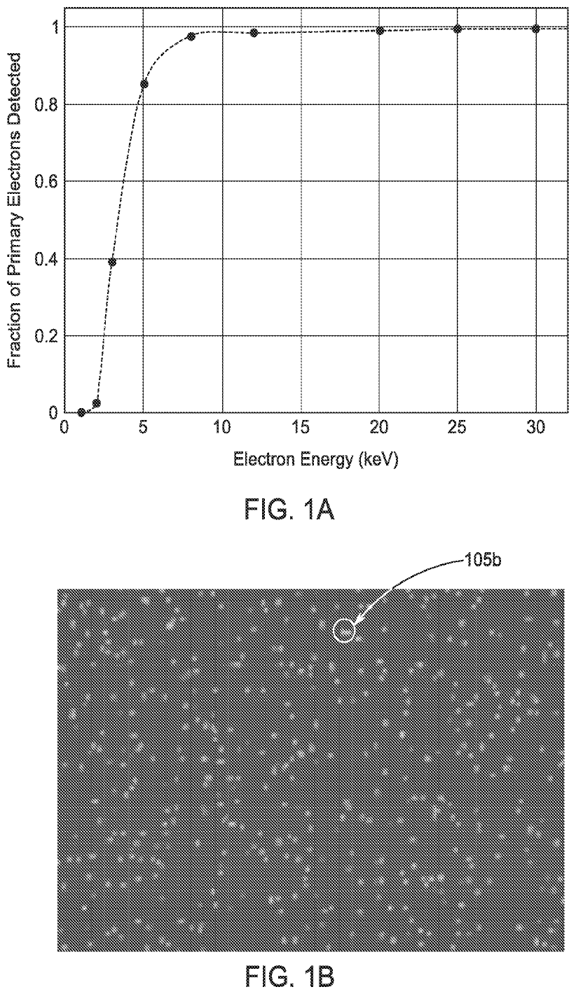

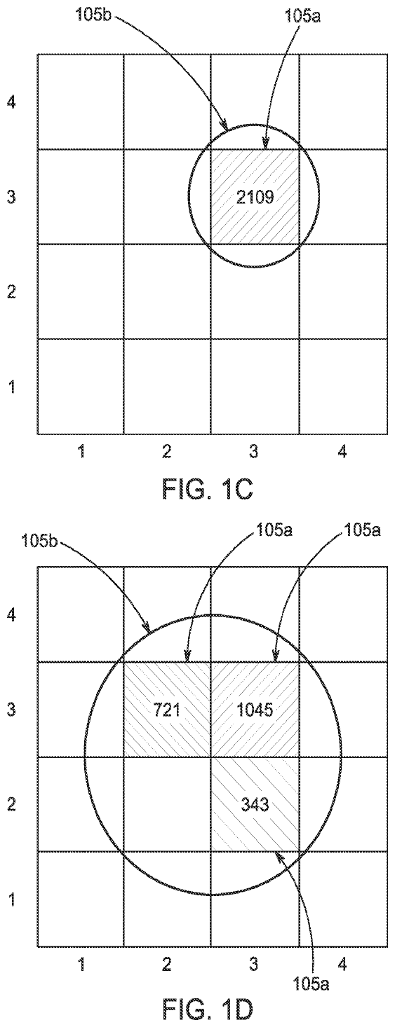

FIG. 1A shows the detected fraction of incident individual electrons as a function of electron energies (simulated and experimental), according to an embodiment. Notably, the dashed line shows simulation results, whereas the solid circles show experimental measurements. For example, simulations can be performed using PENELOPE. See, e.g., Salvat F., Fernandez-Vera J., & Sempau J., “{penelope}-2006: A code system for Monte Carlo simulation of electron and photon transport,” OECD/NEA Data Bank (2006), Issy-les-Moulineaux, France. The simulation results show that electrons are detected with very high efficiency over the range of electron energies from 5 keV to 30 keV and that their behavior closely aligns with theoretical predictions.

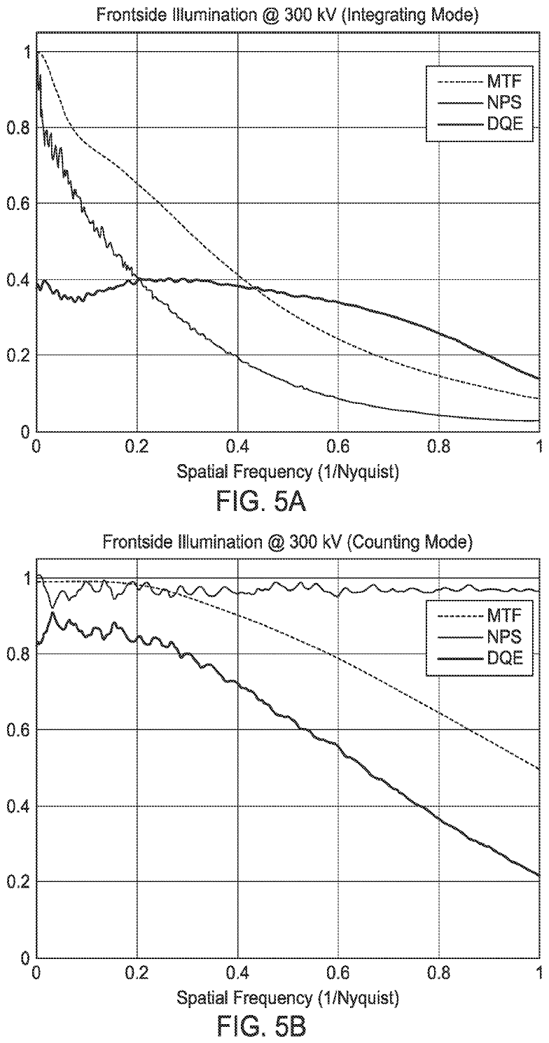

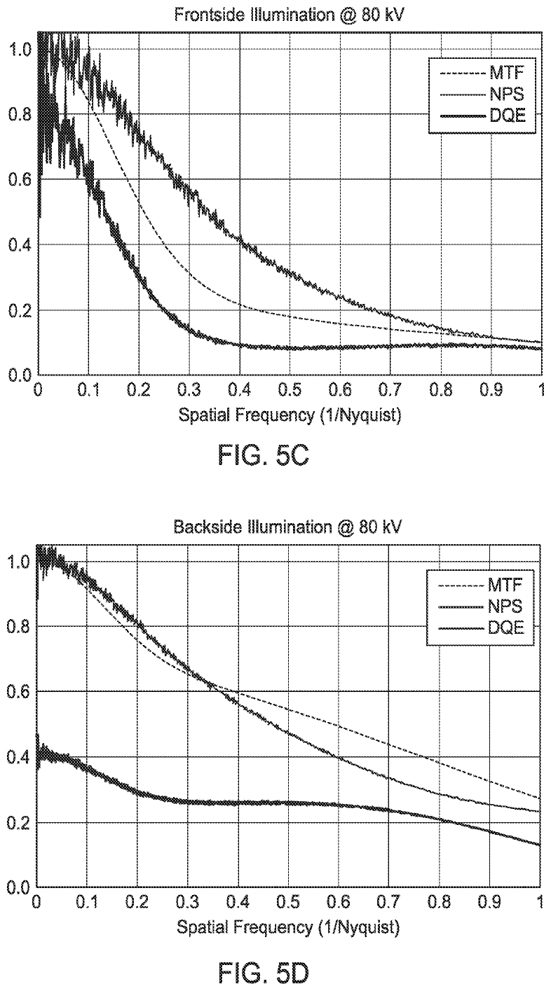

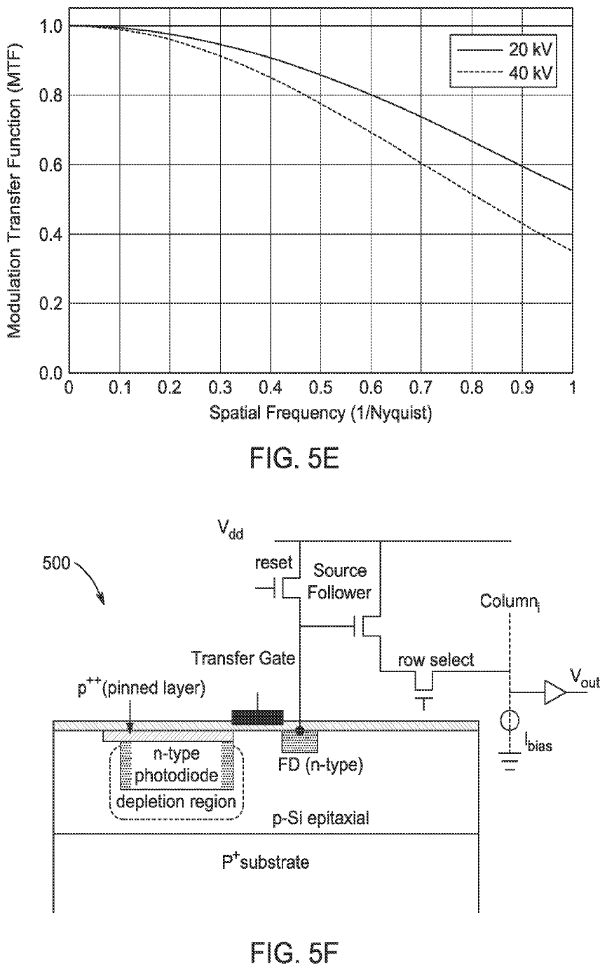

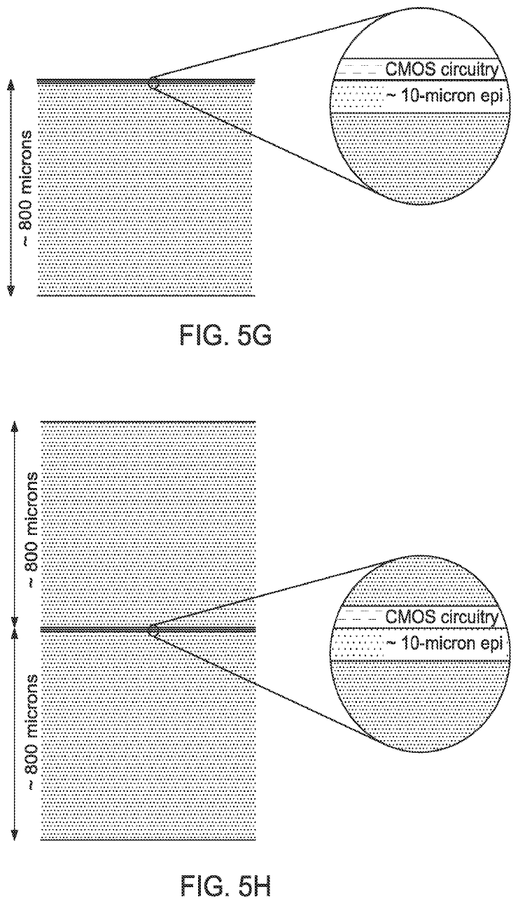

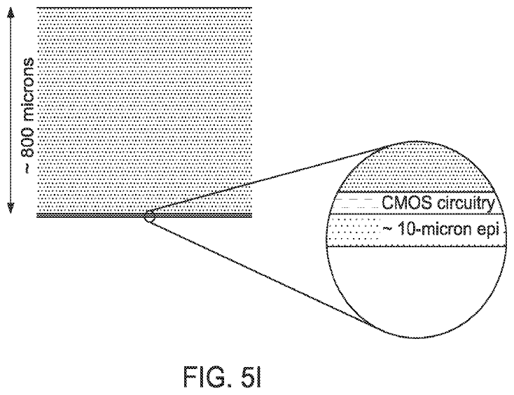

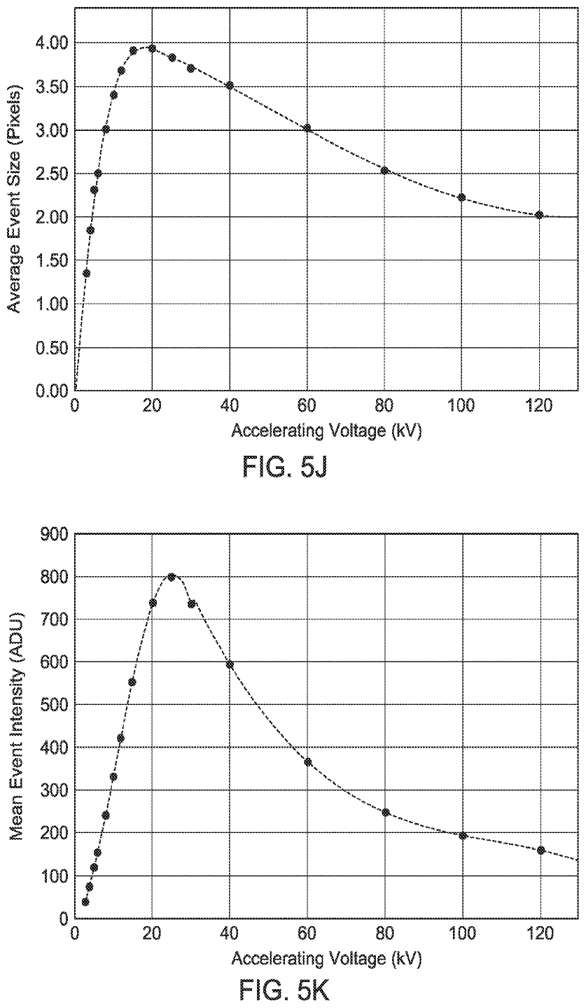

FIG. 1B shows a cropped region of a single frame showing a sparse distribution of single electrons detected by a DED 500 (described later with reference to FIG. 5F), according to an embodiment. The frame can be part of an EBSD acquisition of a sparse distribution of single electrons from a single-crystal silicon (Si) sample with an accelerating voltage of 12 kV and a beam current of 50 pA. The location and energy of a detected electron (also referred to as a detected event or a detection event) can be detected at a single pixel 105a. For example, FIG. 1C shows a schematic of a single electron detection event at a single pixel 105a in DED 500, according to an embodiment. The location and energy of a detected electron can also be detected over more than one of the single pixel 105a in DED 500. For example, FIG. 1D shows a schematic of a single electron detection event over multiple pixels 105a in DED 500 detecting the event, according to an embodiment.

In essence, the schematic representations shown in FIGS. 1C and 1D illustrate what happens when an incident electron strikes a pixel: that pixel registers an energy of detection at its location (see FIG. 1C). If an incident electron strikes multiple pixels at once (e.g., along a border or interface between multiple pixels, or along an edge of one or more pixels), the energy of detection is spread out across multiple pixels (see FIG. 1D). Here, a cluster is defined when one or more of these pixels register an energy of detection that is above a predetermined threshold. Such a cluster may include several pixels if a) the energy of detection is above the predetermined threshold, and b) those several pixels are close together. Such a cluster may also include only one pixel if the energy of detection is above the predetermined threshold. Such clusters are surrounded by pixels having energies of detection that are below the predetermined threshold (i.e., dark pixels). Thus, on a frame, one may identify the location of a cluster (i.e., representative of an incident electron strike) based on its cluster energy, which is the sum of all detection energies for all pixels in that cluster. From this, one may then generate an image of all the identified clusters based on the various cluster energies.

As used herein, a cluster or each cluster may include: (1) a single isolated pixel with an energy of detection above a predetermined threshold, and/or (2) two adjacent pixels, each of which have the energy of detection above the predetermined threshold, and/or (3) three or more “connected” pixels (or adjacent pixels), each of which have the energy of detection above the predetermined threshold, and such that each pixel in the cluster is adjacent (i.e., beside or diagonal to) another pixel in the cluster. Each cluster is separated from other clusters by the presence of pixels having an energy of detection below the predetermined threshold, thereby separating pixels in one cluster from those of another cluster.

In an embodiment, the detected event, whether detected at the single pixel 105a or over the more than one single pixel 105a, can be represented as a cluster 105b. That is, the cluster 105b, as shown in FIGS. 1C and 1D, can be understood to mean one or more of the single pixels 105a arranged within a predetermined distance to one another. For example, the cluster 105b in FIG. 1D shows three of the single pixels 105a adjacent to one another.

The single pixel 105a can include an energy of detection. To determine the pixel(s) 105a included in the cluster 105b, any of the pixel(s) 105a having an energy of detection above a predetermined threshold are identified. Of those identified, a pixel 105a that is within a predetermined distance of another such pixel 105a are grouped together. This can be repeated for all of the identified pixel(s) 105a in the single frame. For one of the pixels 105a not having another of the pixels 105a within the predetermined distance, the cluster 105b includes just the one single pixel 105a as shown, for example, in FIG. 1C. Thus, any two of the clusters 105b can be separated by at least one of the single pixels 105a having an energy of detection below the predetermined threshold. This can, in an example, be visualized as bright spots (e.g., the clusters 105b) in a generated image surrounded and separated by dark spots (e.g., the at least one of the single pixels 105a having the energy of detection below the predetermined threshold), for example, as shown in FIG. 1B. The predetermined threshold and the predetermined distance may be set for the single frame, a stack of frames, or adaptively for the single pixel 105a or the cluster 105b.

The cluster 105b can include a cluster energy, wherein the cluster energy is equal to a summation of the energy of detection for said each of the single pixel 105a included in the cluster 105b. As shown in FIGS. 1C and 1D, the cluster energy in each scenario would be equal (i.e., whether “2109” from one pixel 105a shown in FIG. 1C or “2109” from summed from three pixels 105a (“721,” “1045,” and “343”) shown in FIG. 1D). The location of the cluster 105b can thus be determined by determining a centroid and the cluster energy of the cluster 105b. As shown in FIGS. 1C and 1D, for example, the location would be determined to originate on the same single pixel 105a (i.e., the single pixel 105a located at coordinate (3,3) in the grid array).

Additionally, when an SEM beam current is sufficiently low compared to the frame rate of the DED 500, the DED 500 can record not only the location but also the energy of each detected electron. It may be appreciated that many methods of determining the location of the cluster 105b may be used, for example, determining a brightest pixel, determining a centroid, determining a center of mass (e.g., based on energy intensity distribution), or any combination thereof. It may also be appreciated that the summing of the energies of detection may include subtracting a background that may be determined for a single frame, a stack of frames, or adaptively for the single pixel 105a or the cluster 105b.

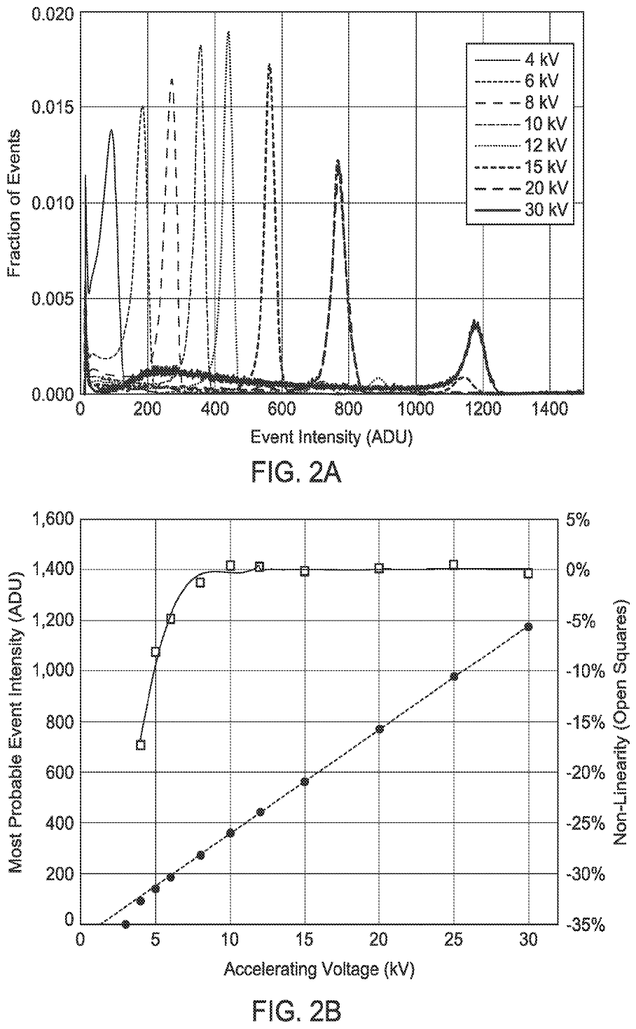

FIG. 2A shows a series of histograms of the detected fraction of incident individual electrons as a function of event intensity for events detected by a direct electron detector (e.g., DED 500 shown in FIG. 5F) at different incident electron energies, according to an embodiment. The event intensity is represented as the number of detected electrons (i.e., counts) per analog-to-digital unit (ADU). The sharpness of the peaks indicates that incident electron energies are determined with high sensitivity and resolution. Note that for some energies, there is a second small peak at 2 times the intensity of a first large peak. Consistent with an embodiment, this can indicate that each of the single pixels 105a (i.e., “blobs”) measured for the higher-intensity peaks represent locations on the DED 500 (shown in FIG. 5F) where two electrons were detected simultaneously. For SEMs (<30 keV), backside illumination (BSI) of electrons is used for electron detection. For TEMs (e.g., at 120 keV), the smaller the spot size is (in the range of 60 keV to 120 keV), the better the results for BSI electron detection.

FIG. 2B shows the measured linearity of response to electron energy of single electrons detected by a direct electron detector (e.g., DED 500 shown in FIG. 5F), according to an embodiment. In FIG. 2B, the closed circles show the measured most-probable event intensity for single electrons, represented as the number of detected electrons (i.e., counts) per ADU, as a function of accelerating voltage (kV). Also in FIG. 2B, the open squares show the non-linearity of the measured most-probable event intensity as a function of accelerating voltage (kV), i.e., the deviation from linearity as determined by a linear fit to the measured most-probable intensity values for accelerating voltages from, for example, 10 kV to 30 kV. The linearity of energy discrimination of the DED 500 can exceed 85% for electrons at 4 keV energy and higher, and can exceed 99.5% for electrons at 10 keV energy and higher. This reproducible energy discrimination can enable energy filtering of EBSD patterns ex post facto, including complex schemes for applying different energy thresholds to different regions of the diffraction pattern.

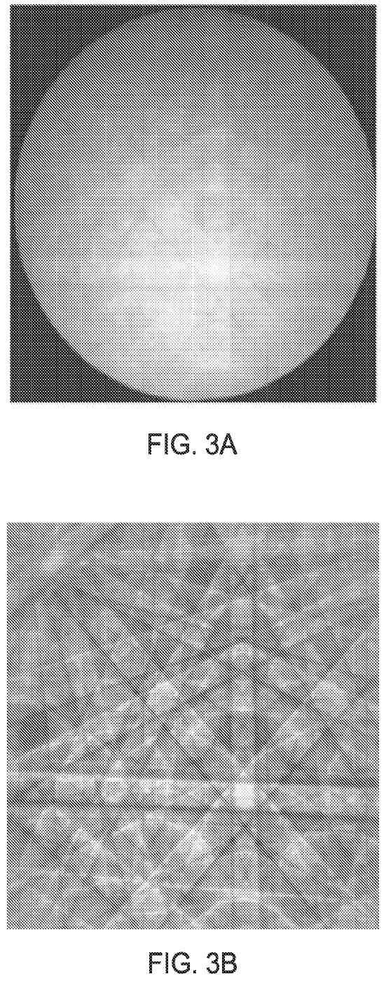

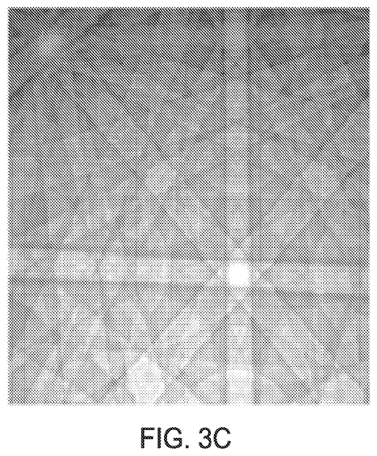

FIG. 3A shows EBSD patterns of single-crystal Si acquired at a beam voltage of 12 kV, a current of 13 nA, and an exposure time of 1 second, using a phosphor+CCD camera, according to an embodiment. For example, FIG. 3A can show a raw experimental pattern without background subtraction.

FIG. 3B shows EBSD patterns of single-crystal Si acquired at a beam voltage of 12 kV, a current of 13 nA, and an exposure time of 1 second, using a direct electron detector (e.g., DED 500 shown in FIG. 5F), according to an embodiment. For example, FIG. 3B also shows a raw experimental pattern without background subtraction. Moreover, FIGS. 3A and 3B have been adjusted to a same contrast range for visual comparison.

FIG. 3C shows simulated EBSD patterns of single-crystal Si acquired at a beam voltage of 12 kV, a current of 13 nA, and an exposure time of 1 second, according to an embodiment. The simulation was performed using EMsoft, and depicts the theoretical limits of resolution and signal-to-noise ratio for an ideal detector.

Many more features are visible in FIG. 3B compared to FIG. 3A, even before background subtraction or energy filtering. Consistent with the described embodiments, the inventors have demonstrated the ability to provide detail closely approaching the theoretical limits of resolution and signal-to-noise ratio, e.g., as shown by the simulation in FIG. 3C.

For electron counting applications, the DED 500 can be configured to render a readout rate of, for example, 281 frames/second in, for example, a camera with a resolution of 2048×2048 pixels, with a pixel size of, for example, 13 μm. In another example, DED 500 can be configured to render a readout rate of, for example, 2400 frames/second in, for example, a camera with a resolution of 1024-1024 pixels, with a pixel size of, for example, 15 μm. A readout rate range of the DED 500 can be, for example, greater than 50 frames/second, greater than 500 frames/second, greater than 5,000 frames/second, greater than 50,000 frames/second, or greater than 100,000 frames/second. A pixel resolution range for the DED 500 can be, for example, less than 8192×8192 pixels, or less than 4096×4096 pixels, or less than 2048×2048 pixels, or less than 1024×1024 pixels, or less than 512×512 pixels. A range of the pixel size can be, for example, less than 1,000 μm, or less than 500 μm, or less than 200 μm, or less than 100 μm, or less than 50 m, or less than 25 μm, or less than 10 μm.

The fast readout speed and high sensitivity of the DED 500 can enable the counting of individual electrons and thereafter accurate calibration of the pixel intensity values to electron energies. Energy filtering can be demonstrated for a dataset collected at low currents, where individual electrons are both counted and characterized based on their energy. The electron counting events can be preserved in a series of fast detector frame readouts, in contrast to signal thresholding on the chip or beam filtering in front of the DED 500. See, e.g., A. Deal, T. Hooghan and A. Eades, Ultramicroscopy (2008) 108: 116. This additional dimension of data provides access to myriad aspects of the electron signal, e.g., the energy distribution on the DED 500.

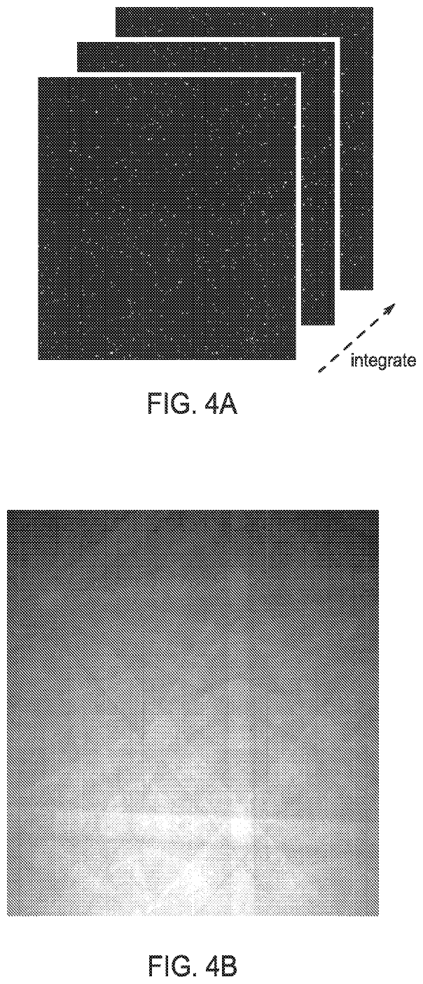

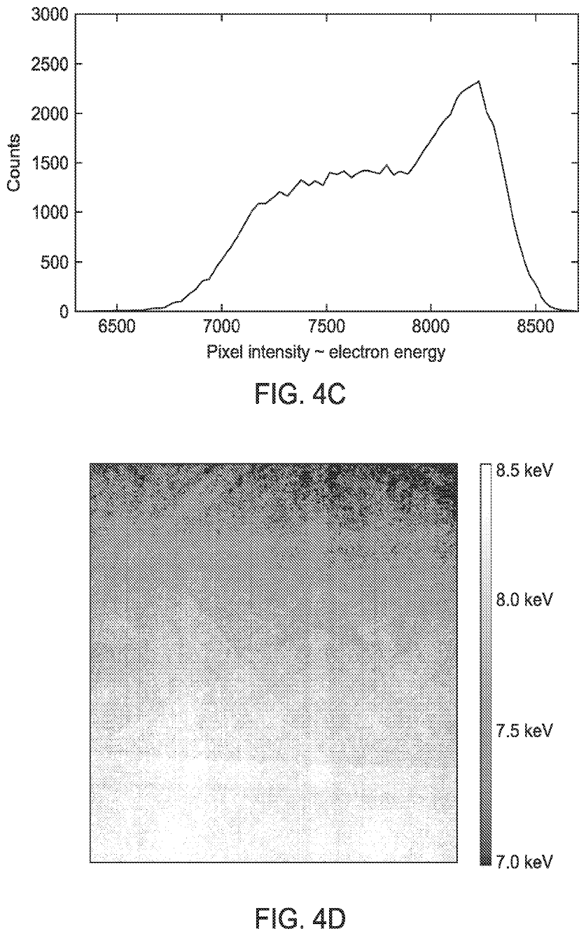

FIGS. 4A-4C show the principle of energy filtered EBSD pattern collection based on electron counting. The data can be acquired, for example, from single-crystal Si using a beam voltage of 12 kV and a beam current of 0.78 pA. The exposure time can be 60 seconds in order to obtain significant statistics while electron counting with a DED having 2048×2048 pixel resolution and operating at a frame rate of 280 frames/second. For each dwell position of the electron beam on the specimen, a series of sparse exposures (i.e., frames) are collected, events in each frame are analyzed for position and energy deposited, and then the results are combined into a multi-dimensional data set containing location information or other suitable representation of spatial information (e.g., X and Y coordinates or polar coordinates), and the number of events per location on the DED 500 and the energy of each event at each location.

FIG. 4A shows a schematic of the integration of fast detector frame readouts acquired for multiple frames, each of which shows a sparse distribution of single electrons detected by a direct electron detector (e.g., DED 500 shown in FIG. 5F), according to an embodiment. For example, 16,860 frames in total can be collected in 60 seconds using a frame rate of 276.4 frames/second. Consistent with an embodiment, 16,860 frames can be collected in 7 seconds with a DED having 1024×1024 pixel resolution and operating at a frame rate of 2400 frames/second.

FIG. 4B shows a multi-dimensional data set of integrated and energy-filtered EBSD patterns based on the frames acquired in FIG. 4A, according to an embodiment. That is, the multi-dimensional data set shows the number and location of detected electrons in an integrated EBSD map acquired by electron counting from the fast detector frame readouts acquired for the multiple frames of FIG. 4A, according to an embodiment.

FIG. 4C shows a distribution of pixel intensities in the integrated and energy-filtered EBSD patterns of FIG. 4B, according to an embodiment. As shown from this distribution, for example, the pixel intensity (in counts) is proportional to the electron energy (in keV). This additional dimension of data provides access to, for example, the electron energy distribution on the direct electron detector (e.g., DED 500 shown in FIG. 5F), which is not presented in the EBSD map shown in FIG. 4B, and which is not available from other detectors. This is illustrated, for example, in FIG. 4D.

FIG. 4D shows the EBSD map of FIG. 4B, but modified to include the additional dimension of data (i.e., the electron energy distribution of FIG. 4C) by applying a grayscale gradient corresponding to electron energies from 7.0 keV (black) to 8.5 keV (white) over the EBSD map shown in FIG. 4B, according to an embodiment.

Consistent with an embodiment, the DED 500 and fast readout speed allow the use of innovative sampling schemes for the collection of EBSD patterns. For high-speed mapping applications, the DED 500 can collect from hundreds of user-defined pixel rows at a rate of, for example, >4000 frames/second, and more preferably >100,000 frames/second. The efficient sampling of selected parts of the EBSD pattern coupled with Hough-transform-based indexing, or dictionary indexing using, for example, EMsoft, or spherical indexing with, for example, EMSphInx, can give rise to ultra-fast EBSD orientation mapping. See, e.g., S. Singh, F. Ram and M. De Graef, Microscopy and Microanalysis (2017), 23: 212; see also W. C. Lenthe, S. Singh, and M. De Graef, Ultramicroscopy (2019), 207: 112841.

The performance of DED 500 as it relates to sensitivity and ability to resolve fine features can be described by, for example, the detective quantum efficiency (DQE), which is computed from Noise Power Spectrum (NPS) and Modulation Transfer Function (MTF). (The DQE is defined as the ratio of the square of the output signal to noise ratio (S/N)ₒᵤₜ to the square of the input signal-to-noise ratio (S/N)ᵢₙ, and provides a measure of the quality with which incident electrons are recorded.) For a MAPS DED, as the electron accelerating voltage decreases, the DQE can degrade. The primary reason for the degradation in DQE can be due to the increase in the size of the charge cloud produced by an interacting electron, which essentially blurs the image (i.e., reducing MTF).

FIG. 5A shows the DQE at 300 keV for a frontside-illuminated MAPS detector operated in integrating mode. And, FIG. 5B shows the DQE at 300 keV for a frontside-illuminated MAPS detector operated in electron counting mode, which illustrates the nearly perfect DQE obtainable with a direct electron detector (e.g., DED 500 shown in FIG. 5F) at 300 keV. The DQE curve shown in FIG. 5B for counting mode operation is very close to the theoretical maximum DQE that can be attained (40.5% at Nyquist). Notably, this demonstrates that frontside-illuminated MAPS direct detection sensors are effective at acquiring high-energy (e.g., ≥200 keV) electron images.

FIG. 5C shows the MTF and DQE at 80 keV for a frontside-illuminated MAPS detector operated in integrating mode. And, FIG. 5D shows the MTF and DQE at 80 keV for a backside-illuminated (BSI) MAPS direct electron detector (e.g., DED 500 shown in FIG. 5F) operated in integrating mode. Notably, FIGS. 5C and 5D demonstrate that frontside-illuminated MAPS detectors become ineffective as the electron energy is decreased, but backside-illuminated devices, such as BSI MAPS direct electron detectors, are effective at these lower electron energies. By comparison to FIG. 5A, the DQE performance shown in FIG. 5C is degraded at the lower electron energies, especially at higher spatial frequencies. This can be due primarily to the larger cloud of electrons produced for every primary electron interacting with the sensor. Although not shown, counting mode DQE curves at 100 keV and 80 keV would be even further degraded and the sensor would not function at all at electron energies typically used in the SEM. DQE results are relatively insensitive to readout shutter mode (e.g., Global Shutter (GS) versus Rolling Shutter (RS)), so results for only one shutter mode are shown (RS).

FIG. 5E shows the MTF at 20 keV and 40 keV for a backside-illuminated MAPS direct electron detector (e.g., DED 500 shown in FIG. 5F) operated in integrating mode. Notably, this demonstrates that backside-illuminated MAPS direct detection detectors are effective at collecting data at the energy range used for EBSD on an SEM (e.g., <30 kV).

FIG. 5F shows a schematic cross-section of a frontside-illuminated MAPS DED 500, which has been modified such that some of the substrate material has been removed, according to an embodiment. Normally, for a MAPS detector, electrons enter from the top, pass through the electronics layer, the epi layer, and into the substrate. The electronics layer is on the order of, for example, 5 μm thick, the epi layer ranges in thickness between, for example, 5 μm and 18 μm thick, and the substrate is thinned from the back side to leave a layer that may range from, for example, a few μm to a few tens of μm. This modification (i.e., backside substrate thinning) is performed so that electrons do not backscatter in the substrate and re-enter the epi layer and deposit more charge in areas away from where they originally entered (i.e., contributing noise).

FIG. 5G shows a schematic cross-section of a portion of the MAPS DED 500 of FIG. 5F, before substrate thinning, showing the relative thickness of the substrate compared to the thickness of the epitaxial layer and the circuitry layer, according to an embodiment. Alternatively, however, for MAPS DED 500, electrons can be caused to enter from the bottom or the backside through a thin layer of substrate or through no substrate. To accommodate the substrate thinning, or the elimination of the substrate, the MAPS DED 500 may be bonded to a handling wafer on the electronics side to facilitate handling during substrate thinning or removal and subsequent incorporation into a mechanical system.

FIG. 5H shows a schematic cross-section of a portion of the MAPS DED 500 of FIG. 5F, after a handling wafer has been bonded to the CMOS circuitry side, according to an embodiment. The bonding may be performed using an oxide-oxide bond or by another bonding method.

FIG. 5I shows a schematic cross-section of a portion of a MAPS DED 500 after removal of the substrate portion of the original wafer upon which the MAPS DED 500 was fabricated, leaving the epitaxial layer exposed, according to an embodiment. The substrate can be removed using grinding, chemical-mechanical polishing, chemical etching, or other methods. Some of the substrate material may be left in place, but more preferably, all of the substrate is removed. The newly exposed surface of the epitaxial silicon layer may be treated by ion implantation followed by thermal or laser annealing to result in a net positive potential at the surface so that electrons are repulsed toward the depletion region under the pinned photodiode rather than trapped at the back surface. Alternatively, the back surface may be treated using molecular beam epitaxial (MBE) growth to deposit at least one layer, or more preferably alternating layers, of P type and N type material. Alternatively, the newly exposed epitaxial silicon surface may be treated by any other method that results in a net positive potential at the newly exposed interface. The MAPS DED 500 can be installed in a camera, the camera providing electrical power, control signals, and a path for signal data. The MAPS DED 500 may be electrically connected to a control device such as a computer, or may be installed in a camera, which in turn may be connected to a control device.

FIG. 5J shows a graph of average event size (in pixels) as a function of accelerating voltage (kV), according to an embodiment. Notably, the event size is only 2 pixels for a 6.5 μm pixel sensor at 120 keV. Also of note is that the average event size never exceeds 4 pixels at its maximum, and continues to decrease in size as electron energy decreases from 20 keV. Furthermore, this graph shows that a cluster of pixels representing a detection event on the MAPS DED 500 is generally spread over a small number of pixels. While the graph in FIG. 5J shows the average size of clusters at each electron energy, there is a size distribution of clusters at each electron energy from one pixel to many pixels (e.g., up to approximately 20 pixels).

FIG. 5I shows a graph of mean event intensity (counts per ADU) as a function of accelerating voltage (kV), according to an embodiment. This graph illustrates that the total cluster energy is correlated with the energy of the detected electrons. This graph can also be used to convert the sum of the pixel values of each cluster to the energy of the detected electrons. Notably, the event signal at 120 kV is optimal in that it is sufficiently large to provide good single electron sensitivity, while not so large that the dynamic range of the MAPS DED 500 is consumed. Of particular note is the linear relationship between event intensity and accelerating voltage below about 25 kV. This relationship enables straightforward energy discrimination at electron energies relevant to SEM and EBSD.

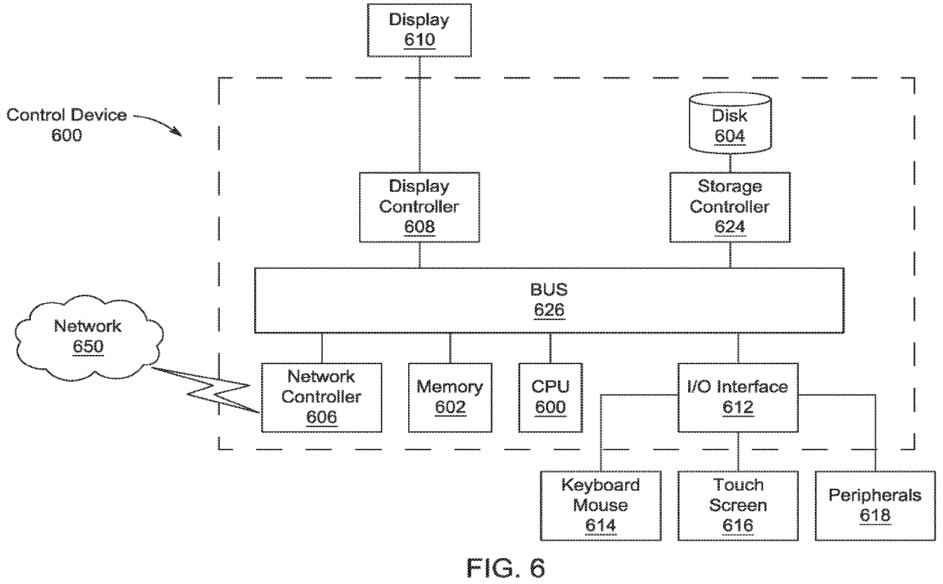

Next, a hardware description of the control device (e.g., a computer) for controlling components of the system including a direct electron detector according to an embodiment is described with reference to FIG. 6. In FIG. 6, the control device includes a CPU 600, which performs the processes described above. The control device may contain a GPU which may perform some or all of the process described above. The control device may contain FPGA(s) or the camera may contain FPGA(s) that perform some or all of the processes described above. The process data and instructions may be stored in memory 602. These processes and instructions may also be stored on a storage medium disk 604 such as a hard drive (HDD) or other portable storage medium, or may be stored remotely. Further, the claimed advancements are not limited by the form of the computer-readable media on which the instructions of the inventive process are stored. For example, the instructions may be stored on CDs, DVDs, in FLASH memory, RAM, ROM, PROM, EPROM, EEPROM, or any other information processing device with which the control device communicates, such as a server or computer.

Further, the inventive process may be provided as a utility application, background daemon, or component of an operating system, or combination thereof, executing in conjunction with CPU 600 and an operating system, such as MICROSOFT WINDOWS®, UNIX®, SOLARIS®, LINUX®, APPLE MAC-OS®, or other systems known to those of ordinary skill in the art.

The hardware elements in order to achieve the control device may be realized by various circuitry elements, known to those of ordinary skill in the art. For example, CPU 600 may be an INTEL® XEON® or CORE™ processor, or an AMD® OPTERON™ processor, or may be other processor types that would be recognized by those of ordinary skill in the art. Alternatively, the CPU 600 may be implemented on an FPGA, ASIC, PLD or using discrete logic circuits, as one of ordinary skill in the art would recognize. Further, CPU 600 may be implemented as multiple processors cooperatively working in parallel to perform the instructions of the inventive processes described above.

The control device in FIG. 6 also includes a network controller 606, such as an INTEL® PRO® ETHERNET™ network interface card, for interfacing with network 650. As can be appreciated, the network 650 can be a public network, such as the internet, or a private network, such as an LAN or WAN network, or any combination thereof, and can also include PSTN or ISDN sub-networks. The network 650 can also be wired, such as an ETHERNET™ network, or can be wireless, such as a cellular network including EDGE®, LTE®, 3G, 4G®, 5G™, or the like, or such as RF, BLUETOOTH®, or WIFI®, or any other wireless form of communication, as one of ordinary skill in the art would recognize.

The control device further includes a display controller 608, such as a NVIDIA® GEFORCE® GTX or QUADRO™ graphics adaptor for interfacing with display 610, such as a HEWLETT PACKARD® Z27q G3 QHD display, a HPL2445w LCD monitor, or any other LCD or LED monitor or display. A general purpose I/O interface 612 interfaces with a keyboard and/or mouse 614 as well as a touch screen panel 616 on or separate from display 610. General purpose I/O interface 612 also connects to a variety of peripherals 618, including any peripherals appropriate for use in electron microscopy.

The general purpose storage controller 624 connects the storage medium disk 604 with communication bus 626, which may be an ISA, EISA, VESA, PCI, or similar, for interconnecting all of the components of the control device. The storage controller may be a RAID controller connected to one or more M.2 or U.2 drives to achieve write speeds high enough to allow continuous acquisition of data from a fast DED camera. A description of the general features and functionality of the display 610, keyboard and/or mouse 614, as well as the display controller 608, storage controller 624, network controller 606, sound controller 620, and general purpose I/O interface 612 is omitted, as these would be understood by those of ordinary skill in the art.

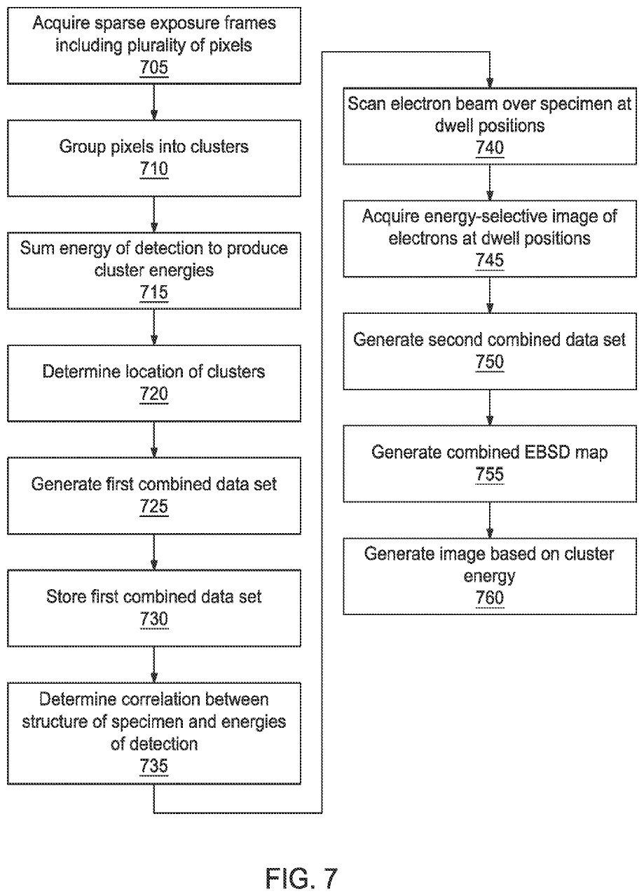

FIG. 7 is a flow chart illustrating steps of a method for performing energy sensitive imaging of ionizing radiation, according to an embodiment. In step 705, an electron beam is focused on a least one position on a specimen and a plurality of sparse exposure frames is acquired, each sparse exposure frame including a plurality of pixels, each pixel of the plurality of pixels in said each sparse exposure having an energy of detection and a location. For example, a first frame of the plurality of sparse exposure frames is acquired.

In step 710, pixels of the plurality of pixels having an energy of detection above a predetermined threshold and a location along with at least one other pixel also having an energy of detection above the predetermined threshold and being within a predetermined distance of the location are grouped into at least one cluster. The predetermined threshold may be set for a single frame, a stack of frames, or adaptively for each pixel or at least one cluster. In step 715, the cluster energy is determined. The cluster energy may be calculated by summing the energy of detection from individual pixels within the at least one cluster. The summing step may include subtracting a background that may be calculated for a single frame, a stack of frames, or adaptively for each pixel or at least one cluster.

In step 720, a location of the at least one cluster is determined. The location can be based on a distribution and an intensity of the energy of detection from each pixel in the at least one cluster. Further, the method of determining location may use center of mass, brightest pixel, centroid, or other method. The location of the cluster includes an X coordinate and a Y coordinate or other suitable representation of spatial information (in any coordinate system).

In step 725, a first combined data set is generated, including the acquired first frame, the first frame including a catalog of the cluster energy of the at least one cluster and the location of the at least one cluster.

In step 730, the first combined data set is stored in a memory.

In step 735, a correlation between a structure or other property of a specimen and the first combined data set is determined.

In step 740, a beam of electrons can be scanned on a specimen. The scanning may adopt a raster pattern, wherein the beam of electrons occupies a plurality of dwell positions located over the specimen.

In step 745, for each position of the plurality of dwell positions, an energy-selective image of the electrons is acquired as in steps 705 through 735.

In step 750, a second combined data set is generated, including the acquired energy-selective image of the electrons for each position of the plurality of dwell positions.

In step 755, a combined EBSD map is generated including the second and subsequent combined data sets having the energy-selective image of the electrons for each position of the plurality of dwell positions.

In step 760, an image is generated based on the cluster energy. In one example, the image of the at least one cluster is generated based on a number of the at least one cluster having the cluster energy exceeding a predetermined cluster energy for each determined location of the at least one cluster. In another example, the image of the at least one cluster is generated based on a number of the at least one cluster having the cluster energy below a predetermined cluster energy for each determined location of the at least one cluster. In another example, the image of the at least one cluster is generated based on a number of the at least one cluster having the cluster energy within a predetermined cluster energy range for each determined location of the at least one cluster. In another example, the image of the at least one cluster is generated based on a corresponding energy of detection of said each pixel of the plurality of pixels grouped into the at least one cluster.

Numerous modifications and variations are possible in light of the above description. It is therefore to be understood that within the scope of the appended claims, the invention may be practiced otherwise than as specifically described herein.

Thus, the foregoing discussion discloses and describes exemplary embodiments of the present invention. As will be understood by those of ordinary skill in the art, the invention may be embodied in other specific forms without departing from the spirit or essential characteristics thereof. Accordingly, the disclosure of the invention is intended to be illustrative, but not limiting of the scope of the invention or that of the claims. The disclosure, including any readily discernible variants of the description herein, defines, in part, the scope of the foregoing claim terminology such that no inventive subject matter is dedicated to the public.

Described embodiments may also be as set forth in the following parentheticals.

(1) A method of performing energy sensitive imaging of ionizing radiation, including: acquiring a first frame, the first frame including a plurality of pixels, each pixel of the plurality of pixels having an energy of detection and a location: grouping, into at least one cluster, pixels of the plurality of pixels having an energy of detection above a predetermined threshold and a location along with at least one other pixel also having an energy of detection above the predetermined threshold and being within a predetermined distance of the location; summing the energy of detection of all pixels within the grouped at least one cluster to determine a cluster energy; determining a location of the at least one cluster based on a distribution and an intensity of the summed energy of detection of the pixels in the at least one cluster; and generating an image of the at least one cluster based on the determined cluster energy and the determined location of the at least one cluster.

(2) The method of (1), further comprising: generating a first combined data set including the acquired first frame, the first frame including a catalog of the cluster energy of the at least one cluster and the location of the at least one cluster.

(3) The method of either (1) or (2), wherein the image of the at least one cluster is generated based on a number of the at least one cluster having the cluster energy exceeding a predetermined cluster energy for each determined location of the at least one cluster.

(4) The method of either (1) or (2), wherein the image of the at least one cluster is generated based on a number of the at least one cluster having the cluster energy below a predetermined cluster energy for each determined location of the at least one cluster.

(5) The method of either (1) or (2), wherein the image of the at least one cluster is generated based on a number of the at least one cluster having the cluster energy within a predetermined cluster energy range for each determined location of the at least one cluster.

(6) The method of either (1) or (2), wherein the image of the at least one cluster is generated based on a corresponding energy of detection of said each pixel of the plurality of pixels grouped into the at least one cluster.

(7) The method of any one of (1) to (6), further comprising determining a correlation between a structure or a property of a specimen and the first combined data set.

(8) The method of any one of (1) to (7), further comprising scanning a beam of electrons over the specimen in a pattern, the beam of electrons having a plurality of dwell positions located over the specimen; acquiring an energy-selective image of the electrons for each position of the plurality of dwell positions; and generating a second combined data set including the acquired energy-selective image of the electrons for said each position of the plurality of dwell positions.

(9) The method of any one of (1) to (8), further comprising generating a combined electron backscatter diffraction (EBSD) map including the second combined data set having the energy-selective image of the electrons for said each position of the plurality of dwell positions.

(10) The method of any one of (1) to (9), wherein the location of said each pixel of the plurality of pixels and the determined location of the at least one cluster are stored as coordinates.

(11) The method of any one of (1) to (10), further comprising, for a second acquired frame having a second plurality of pixels, each pixel of the second plurality of pixels having an energy of detection and a location, repeating the steps of grouping, into another at least one cluster, said each pixel of the second plurality of pixels into at least one second cluster, summing the energy of detection of all pixels within the grouped at least one second cluster to determine a second cluster energy, determining a location of the at least one second cluster, and generating an image of the at least one cluster and the at least one second cluster.

(12) A detector apparatus, comprising: an array of a plurality of detector elements, each element of the plurality of detector elements including a monolithic active pixel sensor (MAPS) having an epitaxial silicon layer configured to be exposed to backscattered electrons and to prevent charge from being trapped at a surface thereof; and processing circuitry configured to acquire a first frame, the first frame including a plurality of pixels, each pixel of the plurality of pixels having an energy of detection and a location; group, into at least one cluster, pixels of the plurality of pixels having an energy of detection above a predetermined threshold and a location along with at least one other pixel also having an energy of detection above the predetermined threshold and being within a predetermined distance of the location; sum the energy of detection of all pixels within the grouped at least one cluster to determine a cluster energy; determine a location of the at least one cluster based on a distribution and an intensity of the summed energy of detection of the pixels in the at least one cluster; and generate an image of the at least one cluster based on the determined cluster energy and the determined location of the at least one cluster.

(13) The apparatus of (12), wherein the processing circuitry is further configured to generate the image of the at least one cluster based on a number of the at least one cluster having the cluster energy exceeding a predetermined cluster energy for each determined location of the at least one cluster.

(14) The apparatus of either (12) or (13), wherein the MAPS is configured to direct charge to an image sensor charge collection region of the MAPS.

(15) The apparatus of any one of (12) to (14), wherein the MAPS is configured to have a global shutter readout mode.

(16) The apparatus of any one of (12) to (15), wherein the MAPS is configured to operate in synchronization with a scanning pattern of a beam of electrons.

(17) The apparatus of any one of (12) to (16), wherein the processing circuitry is further configured to generate a first combined data set including the acquired first frame, the first frame including a catalog of the cluster energy of at the least one cluster and the location of the at least one cluster.

(18) The apparatus of any one of (12) to (17), wherein the processing circuitry is further configured to determine a correlation between a structure of a specimen and the first combined data set

(19) The apparatus of (18), wherein the processing circuitry is further configured to scan a beam of electrons over the specimen in a pattern, the beam of electrons having a plurality of dwell positions located over the specimen; acquire, for each position of the plurality of dwell positions, an energy-selective image of the electrons; and generate a second combined data set including the energy-selective image of the electrons for said each position of the plurality of dwell positions.

(20) A detector apparatus, comprising: an array of a plurality of detector elements, each detector element of the plurality of detector elements being configured to detect ionizing radiation and to convert the detected ionizing radiation into a photo charge value corresponding to an intensity of the detected ionizing radiation; and processing circuitry configured to acquire a first frame, the first frame including a plurality of pixels, each pixel of the plurality of pixels having an energy of detection and a location, group, into at least one cluster, pixels of the plurality of pixels having an energy of detection above a predetermined threshold and a location along with at least one other pixel also having an energy of detection above the predetermined threshold and being within a predetermined distance of the location; sum the energy of detection of all pixels within the grouped at least one cluster to determine a cluster energy; determine a location of the at least one cluster based on a distribution and an intensity of the summed energy of detection of the pixels in the at least one cluster; and generate an image of the at least one cluster based on the determined cluster energy and the determined location of the at least one cluster.

1. A method of performing energy sensitive imaging of ionizing radiation, comprising:
acquiring a first frame, the first frame including a plurality of pixels, each pixel of the plurality of pixels having an energy of detection and a location;
grouping, into at least one cluster, pixels of the plurality of pixels having an energy of detection above a predetermined threshold and a location along with at least one other pixel also having an energy of detection above the predetermined threshold and being within a predetermined distance of the location;
summing the energy of detection of all pixels within the grouped at least one cluster to determine a cluster energy;
determining a location of the at least one cluster based on a distribution and an intensity of the summed energy of detection of the pixels in the at least one cluster; and
generating an image of the at least one cluster based on the determined cluster energy and the determined location of the at least one cluster.

2. The method of claim 1, further comprising generating a first combined data set including the acquired first frame, the first frame including a catalog of the cluster energy of the at least one cluster and the location of the at least one cluster.

3. The method of claim 1, wherein the image of the at least one cluster is generated based on a number of the at least one cluster having the cluster energy exceeding a predetermined cluster energy for each determined location of the at least one cluster.

4. The method of claim 1, wherein the image of the at least one cluster is generated based on a number of the at least one cluster having the cluster energy below a predetermined cluster energy for each determined location of the at least one cluster.

5. The method of claim 1, wherein the image of the at least one cluster is generated based on a number of the at least one cluster having the cluster energy within a predetermined cluster energy range for each determined location of the at least one cluster.

6. The method of claim 1, wherein the image of the at least one cluster is generated based on a corresponding energy of detection of said each pixel of the plurality of pixels grouped into the at least one cluster.

7. The method of claim 2, further comprising determining a correlation between a structure or a property of a specimen and the first combined data set.

8. The method of claim 7, further comprising
scanning a beam of electrons over the specimen in a pattern, the beam of electrons having a plurality of dwell positions located over the specimen;
acquiring an energy-selective image of the electrons for each position of the plurality of dwell positions; and
generating a second combined data set including the acquired energy-selective image of the electrons for said each position of the plurality of dwell positions.

9. The method of claim 8, further comprising generating a combined electron backscatter diffraction (EBSD) map including the second combined data set having the energy-selective image of the electrons for said each position of the plurality of dwell positions.

10. The method of claim 1, wherein the location of said each pixel of the plurality of pixels and the determined location of the at least one cluster are stored as coordinates.

11. The method of claim 1, further comprising, for a second acquired frame having a second plurality of pixels, each pixel of the second plurality of pixels having an energy of detection and a location, repeating the steps of grouping, into another at least one cluster, said each pixel of the second plurality of pixels into at least one second cluster, summing the energy of detection of all pixels within the grouped at least one second cluster to determine a second cluster energy, determining a location of the at least one second cluster, and generating an image of the at least one cluster and the at least one second cluster.

12. A detector apparatus, comprising:
an array of a plurality of detector elements, each element of the plurality of detector elements including a monolithic active pixel sensor (MAPS) having an epitaxial silicon layer configured to be exposed to backscattered electrons and to prevent charge from being trapped at a surface thereof, and
processing circuitry configured to
acquire a first frame, the first frame including a plurality of pixels, each pixel of the plurality of pixels having an energy of detection and a location;
group, into at least one cluster, pixels of the plurality of pixels having an energy of detection above a predetermined threshold and a location along with at least one other pixel also having an energy of detection above the predetermined threshold and being within a predetermined distance of the location;
sum the energy of detection of all pixels within the grouped at least one cluster to determine a cluster energy;
determine a location of the at least one cluster based on a distribution and an intensity of the summed energy of detection of the pixels in the at least one cluster; and
generate an image of the at least one cluster based on the determined cluster energy and the determined location of the at least one cluster.

13. The apparatus of claim 12, wherein the processing circuitry is further configured to generate the image of the at least one cluster based on a number of the at least one cluster having the cluster energy exceeding a predetermined cluster energy for each determined location of the at least one cluster.

14. The apparatus of claim 12, wherein the MAPS is configured to direct charge to an image sensor charge collection region of the MAPS.

15. The apparatus of claim 12, wherein the MAPS is configured to have a global shutter readout mode.

16. The apparatus of claim 12, wherein the MAPS is configured to operate in synchronization with a scanning pattern of a beam of electrons.

17. The apparatus of claim 12, wherein the processing circuitry is further configured to generate a first combined data set including the acquired first frame, the first frame including a catalog of the cluster energy of at the least one cluster and the location of the at least one cluster.

18. The apparatus of claim 17, wherein the processing circuitry is further configured to determine a correlation between a structure of a specimen and the first combined data set.

19. The apparatus of claim 18, wherein the processing circuitry is further configured to
scan a beam of electrons over the specimen in a pattern, the beam of electrons having a plurality of dwell positions located over the specimen;
acquire, for each position of the plurality of dwell positions, an energy-selective image of the electrons; and
generate a second combined data set including the energy-selective image of the electrons for said each position of the plurality of dwell positions.

20. A detector apparatus, comprising:
an array of a plurality of detector elements, each detector element of the plurality of detector elements being configured to detect ionizing radiation and to convert the detected ionizing radiation into a photo charge value corresponding to an intensity of the detected ionizing radiation; and
processing circuitry configured to
acquire a first frame, the first frame including a plurality of pixels, each pixel of the plurality of pixels having an energy of detection and a location;
group, into at least one cluster, pixels of the plurality of pixels having an energy of detection above a predetermined threshold and a location along with at least one other pixel also having an energy of detection above the predetermined threshold and being within a predetermined distance of the location;
sum the energy of detection of all pixels within the grouped at least one cluster to determine a cluster energy;
determine a location of the at least one cluster based on a distribution and an intensity of the summed energy of detection of the pixels in the at least one cluster; and
generate an image of the at least one cluster based on the determined cluster energy and the determined location of the at least one cluster.
